(19) United States
(12) Patent Application Publication
(10) Pub. No.: US 2013/0176698 A1
(43) Pub. Date: Jul. 11, 2013

(54) HIGH FREQUENCY CIRCUIT COMPRISING GRAPHENE AND METHOD OF OPERATING THE SAME

(71) Applicants: Hyeon-jin SHIN, Suwon-si (KR); Jae-young CHOI, Suwon-si (KR); Seong-chan JUN, Seoul (KR); Whan-kyun KIM, Seoul (KR); Hyung-seo YOON, Seoul (KR); Ju-yeong OH, Gimpo-si (KR); Ju-hwan LIM, Seoul (KR)

(72) Inventors: Hyeon-jin SHIN, Suwon-si (KR); Jae-young CHOI, Suwon-si (KR); Seong-chan JUN, Seoul (KR); Whan-kyun KIM, Seoul (KR); Hyung-seo YOON, Seoul (KR); Ju-yeong OH, Gimpo-si (KR); Ju-hwan LIM, Seoul (KR)

(73) Assignees: Industry-Academic Cooperation Foundation, Yonsei University, Seoul (KR); SAMSUNG ELECTRONICS CO., LTD., Suwon-si (KR)

(21) Appl. No.: 13/543,025

(22) Filed: Jul. 6, 2012

(30) Foreign Application Priority Data
Jul. 8, 2011 (KR) 10-2011-0067970

(51) Int. Cl. H05K 1/02; H05K 1/18

(52) U.S. Cl. CPC H05K 1/0242; H05K 1/18
USPC 361/760; 174/257

(57) ABSTRACT

A high frequency circuit includes a first electronic device, a second electronic device, and a graphene interconnection unit including graphene and which connects the first and second electronic devices, where an interlayer distance of the graphene is greater than or equal to about 0.34 nanometer.

### CROSS-REFERENCE TO RELATED APPLICATIONS

This application claims priority to Korean Patent Application No. 10-2011-0067970, filed on Jul. 8, 2011, and all the benefits accruing therefrom under 35 U.S.C. §119, the content of which in its entirety is herein incorporated by reference.

### BACKGROUND

1. Field

The present disclosure relates to a high frequency circuit including graphene and a method of operating the high frequency circuit. More particularly, the present disclosure relates to a high frequency circuit including chemically synthesized graphene with improved productivity and reproducibility.

2. Description of the Related Art

Recently, research into graphene having high current density and long travel distance of free electrons has been conducted, as a replacement of silicon or metal that has been commonly used in electronic devices. Graphene is a material generally having improved electrical characteristics compared to metal, which is widely used in electronic devices, e.g., copper or aluminum. Recently, signals transmitted in high radio frequency fields may be widely used in three-dimensional displays using high-capacity signal transmission, in next generation communication devices that operate at about 3 gigahertz (GHz), and in semiconductor devices using materials as replacements for silicon.

### SUMMARY

Provided is a high frequency circuit with high productivity and reproducibility and with improved electrical properties.

Provided is a method of operating the high frequency circuit.

Additional aspects will be set forth in part in the description which follows and, in part, will be apparent from the description, or may be learned by practice of the presented embodiments.

According to an embodiment of the invention, a high frequency circuit includes a first electronic device, a second electronic device, and a graphene interconnection unit including graphene and which connects the first and second electronic devices, where an interlayer distance of the graphene is greater than or equal to about 0.34 nanometer (nm).

According to another embodiment of the invention, a method of operating a high frequency circuit includes applying a power voltage to the high frequency circuit comprising a graphene interconnection unit, and conveying a current via the graphene interconnection unit in a high frequency field, where an interlayer distance of graphene of the graphene interconnection unit is greater than or equal to about 0.34 nanometer.

### BRIEF DESCRIPTION OF THE DRAWINGS

These and/or other features will become apparent and more readily appreciated from the following description of the embodiments, taken in conjunction with the accompanying drawings of which:

FIG. 1 is a schematic view showing a crystal structure of graphene obtained using a delamination process;

FIG. 2 a schematic view showing a crystal structure of graphene obtained using a growth process;

FIG. 3A is a schematic view showing a structure of an embodiment of a radio frequency (“RF”) interconnection unit having a ground-signal-ground (“GSG”) type electrode shape;

FIG. 3B is an enlarged view of portion A of FIG. 3A.

FIG. 4 shows a transmission electron microscope (“TEM”) image of an embodiment of graphene in a RF interconnection unit;

FIG. 5 shows an interlayer distance of an embodiment of graphene obtained using a delamination process;

FIG. 6 shows a TEM image of an embodiment of a double-layered graphene in a RF interconnection unit;

FIG. 7 is a graph illustrating an interlayer distance of an embodiment of graphene obtained using a growth process;

FIG. 8 is a graph illustrating reflection coefficient (decibel: dB) versus frequency (gigahertz: GHz) of embodiments of graphene obtained according to Examples 1, 3 and 4;

FIG. 9 is a graph illustrating transmission coefficient (dB) versus frequency (GHz) of embodiments of graphene obtained according to Examples 1, 3 and 4;

FIG. 10 is a graph illustrating real impedance (kilohm: kΩ) versus frequency (GHz) of embodiments of graphene obtained according to Examples 1, 3 and 4;

FIG. 11 is a graph illustrating imaginary impedance (kΩ) versus frequency (GHz) of embodiments of graphene obtained according to Examples 1, 3 and 4;

FIG. 12 is a graph illustrating real impedance (kΩ) versus frequency (GHz) of embodiments of graphene obtained according to Examples 1 and 3 and Comparative Examples 1 and 2; and

FIG. 13 is a graph illustrating imaginary impedance (kΩ) versus frequency (GHz) of embodiments of graphene obtained according to Examples 1 and 3 and Comparative Examples 1 and 2.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein/.

A high frequency circuit is a circuit that conveys current and voltage in a high frequency field. In an embodiment, the high frequency circuit may include a material having high electron mobility and high conductivity.

In an embodiment, the high frequency circuit may include graphene as an interconnection unit that connects electronic devices therein. In an embodiment, the graphene may have multi-layered structure including at least two layers. In an embodiment, an interlayer distance of the graphene may be greater than or equal to about 0.34 nanometer (nm).

Graphene generally has a two-dimensional structure, in which carbon atoms are aligned in a hexagonal ring to form a honeycomb structure. Electrons in graphene move at least about 100 times faster than electrons in monocrystalline silicon that is widely used in a semiconductor device, and the conductivity of graphene is at least about 100 times higher than the conductivity of copper. Accordingly, graphene may function as the high-speed interconnection unit when the graphene is used in a high frequency circuit. In an embodiment, the graphene may have a single layer structure or a multi-layer structure. In an embodiment, the graphene may have 1 layer to about 300 layers. In an embodiment, the number of the layers of the graphene may be determined based on the size of electronic devices. The size of the graphene may be defined by width and length. In an embodiment, for example, the width (w) and the length (L) of graphene may be in the range of about 0.001 micrometer (μm) to about 1 millimeter (mm) and in the range of about 0.001 μm to about 100 μm, respectively.

In an embodiment, the graphene may be manufactured using various methods, for example, a delamination process or a growth process. In an embodiment, graphene may have different structural characteristics based on the manufacturing method thereof.

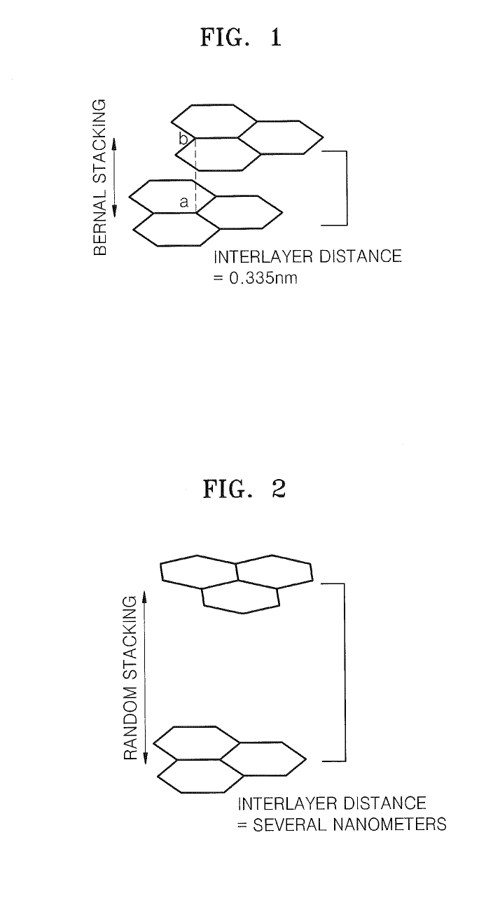

The delamination process includes separating graphene from a material internally including a graphene structure, such as highly oriented pyrolytic graphite (“HOPG”), using a mechanical method (for example, a Scotch™ tape) or a redox process. In the delamination process, obtained graphene may have a micrometer size, may not include a uniform shape of ripped portions, and may not include a constant number of layers, such that productivity and reproducibility of the obtained graphene may deteriorate. Micro-structural characteristics of graphene obtained using the delamination process are shown in FIG. 1. In an embodiment, an interlayer distance of the graphene obtained using the delamination process is about 0.33 nm, and the graphene has a stack structure in which a carbon atom located in position 1 of a hexagonal structure of a lower layer is close to a carbon atom located in position 4 of the hexagonal structure of an upper layer.

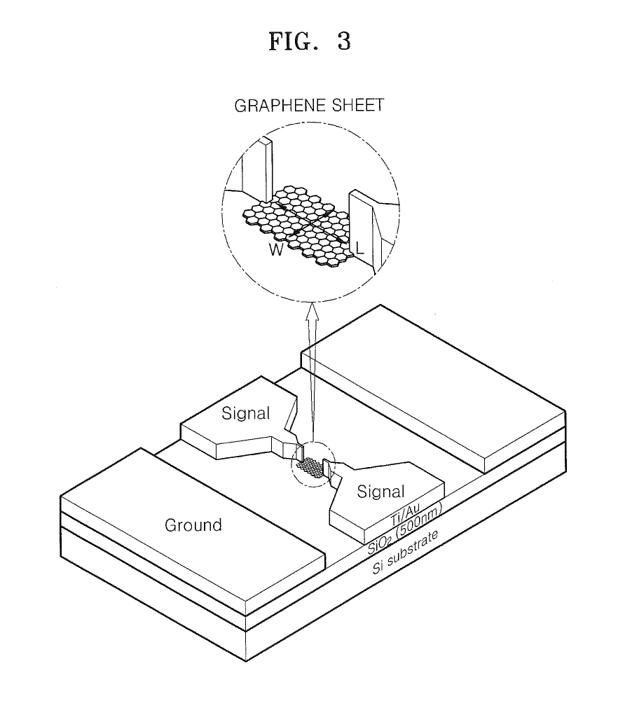

In an alternative embodiment, graphene may be obtained using a growth process. According to the growth process, carbon that is adsorbed to or contained in an inorganic material grows on a surface at a high temperature, or a gaseous carbon source is dissolved in or adsorbed to a catalyst layer at a high temperature and cooled to crystallize the carbon on a surface. In an embodiment, the graphene obtained using the growth process may have an area greater than or equal to about 1 square centimeter (cm²) and have a uniform shape. In an embodiment, the number of layers of the graphene may be adjusted by controlling type and thickness of a substrate or a catalyst, reaction time, cooling rate, and concentrations of reactant gases, for example. In such an embodiment, the graphene manufactured using the growth process has substantially high reproducibility, and may be efficiently mass-produced. Micro-structural characteristics of graphene obtained using the growth process are also shown in FIG. 2. The graphene obtained using the growth process has a randomly stacked structure, and an interlayer distance of graphene obtained using the growth process is greater than or equal to about 0.34 nm.

The graphene obtained using the delamination process and the graphene obtained using the growth process may have different electrical properties due to the structural difference therebetween. The interlayer distance of the graphene obtained using the growth process is greater than the interlayer distance of the graphene that obtained using the delamination process, attraction between layers of the graphene obtained using the growth process is thereby relatively small such that influence of the attraction upon mobility of electrons in the graphene obtained using the growth process is relatively less. In addition, as the number of layer increases, density of electrons increases, thereby increasing conductivity of the entire graphene. Mobility of electrons is relatively low in the graphene obtained using the delamination process due to mutual attraction between layers.

In an embodiment the high frequency circuit includes the graphene obtained using the growth process such that electrical properties, productivity and reproducibility of the high frequency circuit is substantially improved. In an embodiment, for example, a graphene interconnection unit of the high frequency circuit includes graphene having at least two layers spaced apart from each other by a distance greater than or equal to about 0.34 nm.

The graphene interconnection unit has higher conductivity and charge mobility than a copper interconnection unit conventionally used in an integrated circuit. The graphene interconnection unit has higher conductivity than the copper interconnection unit. Due to high conductivity, surface scattering that deteriorates conductivity of the interconnection unit may be effectively prevented by a nano-scale size, for example, 100 nm or less. The graphene interconnection unit has a high frequency current carrying capacity and high conductivity, such that the graphene interconnection unit may be applied to high-speed applications including a high frequency nano-scale circuit with improved efficiency.

In an embodiment, the graphene interconnection unit may be used as the interconnection unit in a variety of high frequency applications, for example, a semiconductor chip that operates at a high clock frequency of about 1 gigahertz (GHz) or higher, or a wireless frequency (“RF”) and a microwave circuit, which operate at a high frequency of about 1 GHz or higher such as mobile phones or wireless networks. In an embodiment, the graphene interconnection unit may be used to interconnect active type devices, passive type devices, and combinations thereof which operate at a high frequency of about 1 GHz or higher. In an embodiment, for example, the graphene interconnection unit may be used to interconnect field effect transistors (“FETs”).

In an embodiment, the graphene interconnection unit may include a single piece/unit of graphene or a plurality of pieces/units of graphene arrayed in parallel.

In an embodiment of the high frequency circuit, the graphene interconnection unit connects a first electronic device and a second electronic device, where the first electronic device sends an electrical signal to the second electronic device via the graphene interconnection unit. In an embodiment, the electrical signal may have a frequency in a range of about 1 megahertz (MHz) to about 0.8 GHz. In an alternative embodiment, the electrical signal may have a frequency of about 0.8 GHz or higher. In another alternative embodiment, for example, the electrical signal may have a frequency in the range of about 2 GHz to about 300 terahertz (THz), or in a range of about 5 GHz to about 300 GHz.

In an embodiment, a method of operating the high frequency circuit may include applying a power voltage to the high frequency circuit including the graphene interconnection unit, and conveying current via the graphene interconnection unit in a high frequency field. In such an embodiment, the graphene interconnection unit may interconnect transistors or various electronic devices.

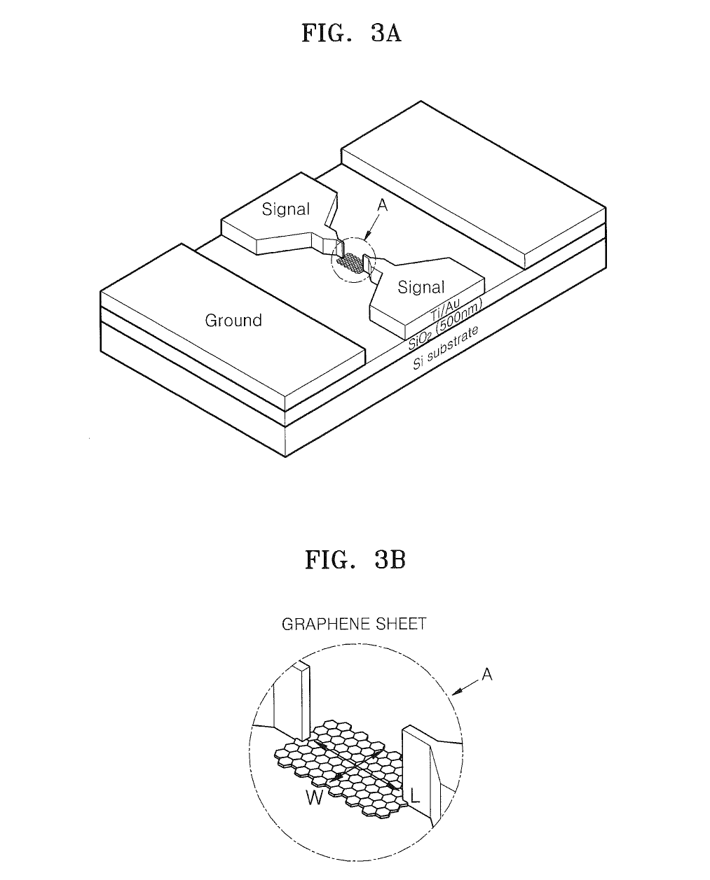

FIG. 3A is a schematic view showing a structure of an embodiment of a radio frequency (“RF”) interconnection unit having a ground-signal-ground (“GSG”) type electrode shape, and FIG. 3B is an enlarged view of portion A of FIG. 3A.

In an embodiment, graphene formed using chemical vapor deposition (“CVD”) is transferred onto an oxidized high resistance p-doped Si wafer (e.g., ρ>10 Ω·cm) having a SiO₂ layer with a thickness in a range from about 400 nm to about 500 nm, and a pattern is formed by photolithography and dry etching. Metallic electrodes having a double layer (e.g., about 20 nm of Ti/about 100 nm of Au) may be formed on the graphene by e-beam lithography and metal evaporation. Graphene is disposed between the electrodes. In an embodiment, a distance between the electrodes may be in the range of about 0.001 μm to about 100 μm. In an alternative embodiment, the distance between the electrodes may be in the range of about 0.001 gm to about 1 mm.

Hereinafter, one or more embodiments of the invention will be described in detail with reference to the following examples. However, these examples are not intended to limit the purpose and scope of the invention.

### EXAMPLE 1

FIG. 3 schematically shows a structure of an embodiment of a RF interconnection unit having a GSG type electrode to measure high frequency transportation characteristics.

An embodiment of graphene is prepared by transferring single-layered graphene grown using CVD onto an oxidized high resistance p-doped Si wafer (ρ>10 Ω·cm) having a SiO₂ layer with a thickness of about 500 nm, and adjusting the width w thereof to about 3 μm using photolithography and dry etching. Metallic electrodes having a double layer (about 20 nm of Ti/about 1 μm of Au) were formed on the graphene by e-beam lithography and metal evaporation. The electrodes were interconnected with each other via the graphene and a distance between the electrodes is adjusted such that L=about 5 μm (w/L=about 0.60).

### EXAMPLE 2

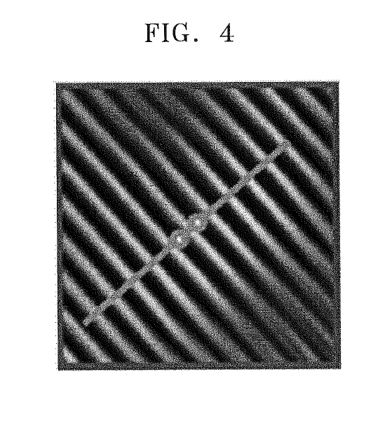

An embodiment of graphene was prepared by twice transferring single-layered graphene grown using CVD onto an oxidized high resistance p-doped Si wafer (ρ>10 Ω·cm) having a SiO₂ layer with a thickness of about 500 nm to form double-layered graphene, and adjusting the width w thereof to about 3 μm by photolithography and dry etching. Metallic electrodes having a double layer (about 20 nm of Ti/about 100 nm of Au) were formed on the graphene by e-beam lithography and metal evaporation. As shown in FIG. 4, the electrodes were interconnected with each other via the graphene and a distance between the electrodes was adjusted such that L=about 5 μm (w/L=about 0.60). An interlayer distance of the graphene formed under the electrodes was about 0.38 nm.

### EXAMPLE 3

An embodiment of graphene was prepared transferring three single-layered graphene grown using CVD onto an oxidized high resistance p-doped Si wafer (ρ>10 Ω·cm) having a SiO₂ layer with a thickness of about 500 nm to form a triple-layered graphene, and adjusting the width w thereof to about 3 μm by photolithography and dry etching. Metallic electrodes having a double layer (about 20 nm of Ti/about 100 nm of Au) were formed on the graphene by e-beam lithography and metal evaporation. As shown in FIG. 4, the electrodes were interconnected with each other via the graphene and a distance between the electrodes was adjusted such that L=about 5 μm (w/L=about 0.60). An interlayer distance of the graphene formed under the electrodes was about 0.38 nm.

### EXAMPLE 4

An embodiment of graphene was prepared by transferring four single-layered graphene grown using CVD onto an oxidized high resistance p-doped Si wafer (ρ>10 Ω·cm) having a SiO₂ layer with a thickness of about 500 nm to form quad-layered graphene, and adjusting the width w to about 6 μm by photolithography and dry etching. Metallic electrodes having a double layer (about 20 nm of Ti/about 100 nm of Au) were formed on the graphene by e-beam lithography and metal evaporation. As shown in FIG. 4, the electrodes were interconnected with each other via the graphene and a distance between the electrodes was adjusted such that L=about 5 μm (w/L=about 1.2). An interlayer distance of the graphene formed under the electrodes was about 0.38 nm.

### EXAMPLE 5

An embodiment of graphene was prepared by transferring a single-layered graphene grown using CVD onto an oxidized high resistance p-doped Si wafer (ρ>10 Ω·cm) having a SiO₂ layer with a thickness of about 500 nm, and adjusting the width w thereof to about 6 μm using photolithography and dry etching. Metallic electrodes having a double layer (about 20 nm of Ti/about 1 μm of Au) were formed on the graphene by e-beam lithography and metal evaporation. The electrodes were interconnected to each other via the graphene and a distance between the electrodes was adjusted such that L=about 5 μm (w/L=about 1.2).

### EXAMPLE 6

An embodiment of graphene was prepared by twice transferring a single-layered graphene grown using CVD onto an oxidized high resistance p-doped Si wafer (ρ>10 Ω·cm) having a SiO₂ layer with a thickness of about 500 nm to form a double-layered graphene, and adjusting the width w thereof to about 6 μm by photolithography and dry etching. Metallic electrodes having a double layer (about 20 nm of Ti/about 100 nm of Au) were formed on the graphene by e-beam lithography and metal evaporation. As shown in FIG. 4, the electrodes were interconnected with each other via the graphene and a distance between the electrodes was adjusted such that L=about 5 μm (w/L=about 1.2). An interlayer distance of the graphene formed under the electrodes was about 0.38 nm.

### EXAMPLE 7

An embodiment of graphene was prepared by transferring three single-layered graphene grown using CVD onto an oxidized high resistance p-doped Si wafer (ρ>10 Ω·cm) having a SiO₂layer with a thickness of about 500 nm to form a triple-layered graphene, and adjusting the width w thereof to about 13 μm by photolithography and dry etching. Metallic electrodes having a double layer (about 20 nm of Ti/about 100 nm of Au) were formed on the graphene by e-beam lithography and metal evaporation. As shown in FIG. 4, the electrodes were interconnected to each other via the graphene and a distance between the electrodes was adjusted such that L=about 5 μm (w/L=about 2.60). An interlayer distance of the graphene formed under the electrodes was about 0.38 nm.

### EXAMPLE 8

Graphene was prepared by transferring four single-layered graphene grown using CVD onto an oxidized high resistance p-doped Si wafer (ρ>10 Ω·cm) having a SiO₂ layer with a thickness of about 500 nm to form a quad-layered graphene, and adjusting the width w to about 13 μm by photolithography and dry etching. Metallic electrodes having a double layer (about 20 nm of Ti/about 100 nm of Au) were formed on the graphene by e-beam lithography and metal evaporation. As shown in FIG. 4, the electrodes were interconnected to each other via the graphene and a distance between the electrodes was adjusted such that L=about 5 gm (w/L=about 2.6). An interlayer distance of the graphene formed under the electrodes was about 0.38 nm.

### COMPARATIVE EXAMPLE 1

Graphene was transferred onto an oxidized high resistance p-doped Si wafer (ρ>10 Ω·cm) having a SiO₂ layer with a thickness of about 500 nm to form single layer graphene using a delamination process. Metallic electrodes having a double layer (about 20 nm of Ti/about 1 μm of Au) were formed on the graphene by e-beam lithography and metal evaporation. The electrodes were interconnected with each other via the graphene, the width w of the graphene was about 7.98 μm, and a distance of the electrodes was adjusted to about 6.87 μm (w/L=about 1.16).

### COMPARATIVE EXAMPLE 2

Graphene was transferred onto an oxidized high resistance p-doped Si wafer (ρ>10 Ω·cm) having a SiO₂ layer with a thickness of about 500 nm to form triple layer graphene using a delamination process. Metallic electrodes having a double layer (about 20 nm of Ti/about 1 μm of Au) were formed on the graphene by e-beam lithography and metal evaporation. The electrodes were interconnected with each other via the graphene, the width w of the graphene was about 7.27 μm, and a distance of the electrodes was adjusted to about 12.91 gm (w/L=about 0.56). An interlayer distance of the graphene formed under the electrodes was about 0.33 nm.

### COMPARATIVE EXAMPLE 3

Graphene was transferred onto an oxidized high resistance p-doped Si wafer (ρ>10 Ω·cm) having a SiO₂ layer with a thickness of about 500 nm to form quad-layer graphene using a delamination process. Metallic electrodes having a double layer (about 20 nm of Ti/about 1 μm of Au) were formed on the graphene by e-beam lithography and metal evaporation. The electrodes were interconnected with each other via the graphene, the width w of the graphene was about 19.18 μm, and a distance of the electrodes was adjusted to about 2.88 μm (w/L=about 6.66). An interlayer distance of the graphene formed under the electrodes was 0.33 nm.

### Exemplary Experiment 1: Measurement of Interlayer Distance

FIG. 4 is a transmission electron microscope (“TEM”) image an embodiment of graphene in a RF interconnection unit. In FIG. 4, quad-layered graphene was formed.

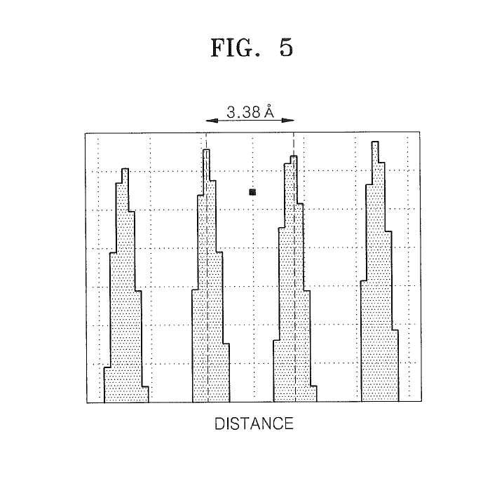

FIG. 5 shows an interlayer distance of an embodiment of graphene obtained using a delamination process, which was measured from a TEM image of a cross-section of the graphene. In such an embodiment, the interlayer distance of graphene was about 0.33 nm.

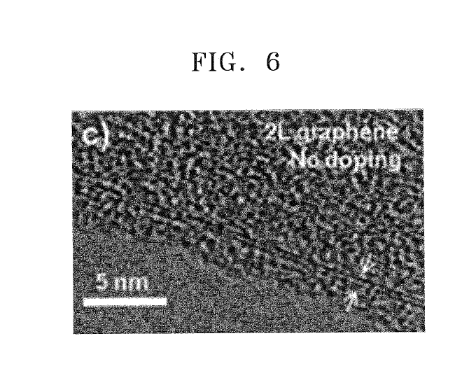

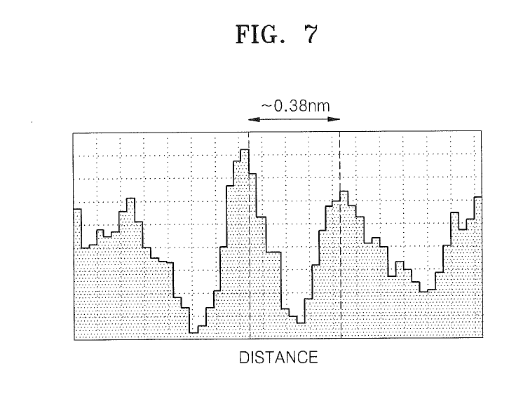

FIG. 6 shows a TEM image of an embodiment of graphene prepared according to Example 2, and FIG. 7 shows an interlayer distance of an embodiment of graphene obtained using a growth process, which was measured from a TEM image of a cross-section of the graphene. The interlayer distance of graphene was about 0.38 nm.

### Exemplary Experiment 2: Measurement of Transmission Characteristics

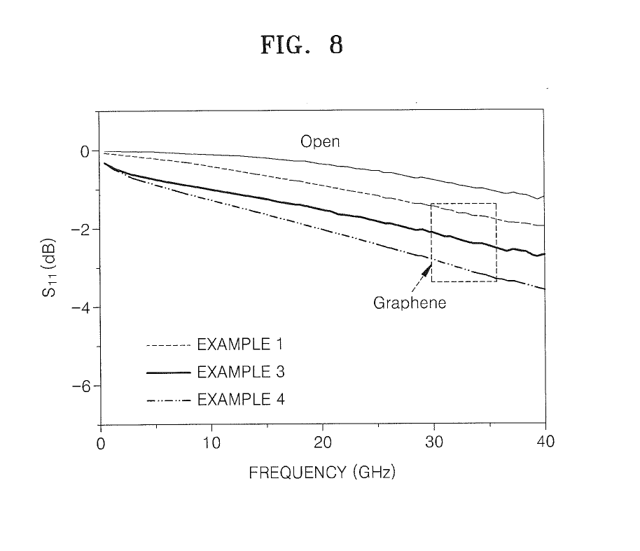

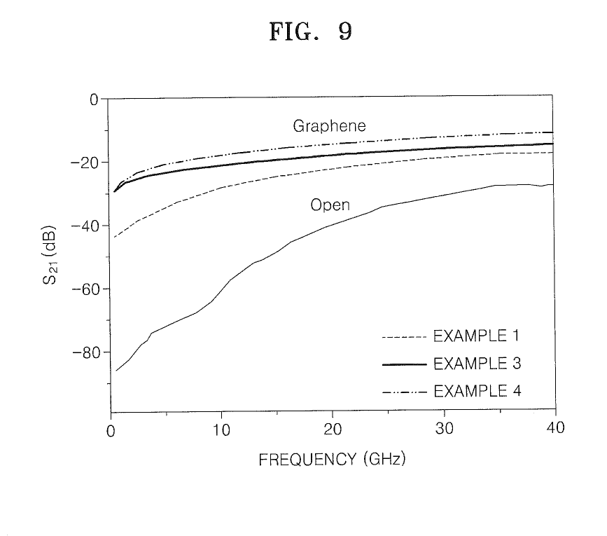

FIGS. 8 and 9 show S-parameters for analyzing transmission characteristics of RF interconnection units prepared according to Examples 1, 3 and 4. FIG. 8 is a graph illustrating reflection coefficient (decibel: dB) versus frequency (GHz) of embodiments of graphene obtained according to Examples 1, 3 and 4, and FIG. 9 is a graph illustrating transmission coefficient (dB) versus frequency (GHz) of embodiments of graphene obtained according to Examples 1, 3 and 4.

S-parameters were measured using a network analyzer (Model No.: Agilent 85225HE01). GSG probes were connected to both ends of the network analyzer, and tips were placed substantially in contact with electrodes of a sample prepared according to standard requirements. Then, a high frequency current was supplied thereto to obtain a potential difference, and then S-parameters were measured using the potential difference.

S₁₁=20 log(V₁ₒᵤₜ/V₁ᵢₙ) (1)

S₂₁=20 log(V₂ₒᵤₜ/V₁ᵢₙ) (2)

S₁₁ denotes a reflection coefficient, and S₂₁ denotes a transmission coefficient. When S₁₁ is low and S21 is high, transmission characteristics may be substantially improved. As shown in FIG. 8, the interconnection unit having the quad-layered graphene prepared according to Example 4 had the lowest reflection coefficient. As shown in FIG. 9, the interconnection unit having the quad-layered graphene prepared according to Example 4 had the highest transmission coefficient. Thus, electrodes having graphene have substantially improved transmission characteristics compared to electrodes not having graphene (open). As shown in the experiment, quad-layered graphene had the most improved transmission characteristics.

### Exemplary Experiment 3: Measurement of Impedance

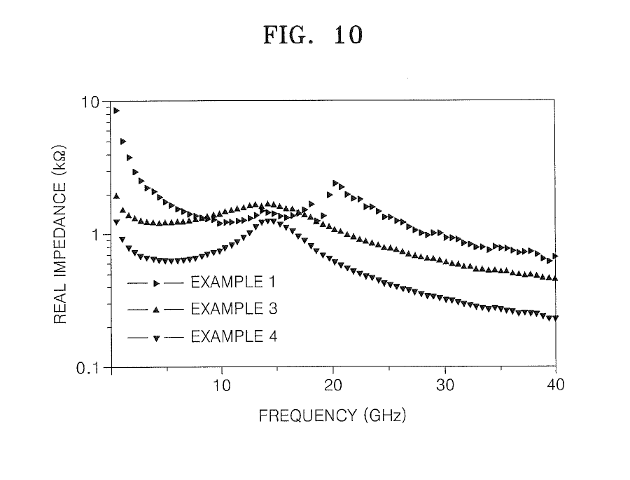

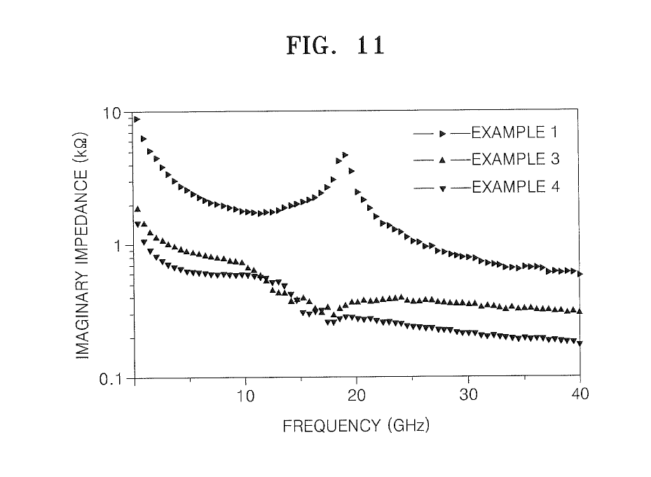

FIG. 10 is a graph illustrating real impedance (kilohm: kΩ) versus frequency (GHz) of embodiments of graphene obtained according to Examples 1, 3 and 4, and FIG. 11 is a graph illustrating imaginary impedance (kΩ) versus frequency (GHz) of embodiments of graphene obtained according to Examples 1, 3 and 4.

As shown in FIGS. 10 and 11, as the number of layers of graphene increases, impedance decreases such that transmission characteristics are improved. As shown in FIGS. 10 and 11, as the frequency increases, impedance substantially decreases, and graphene is thereby efficiently used as the interconnection unit in the high frequency circuit.

### Exemplary Experiment 4: Analysis of Impedance According to Process of Forming Graphene

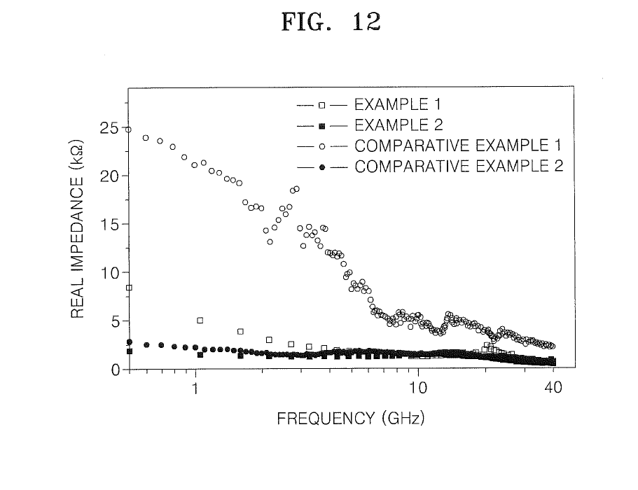

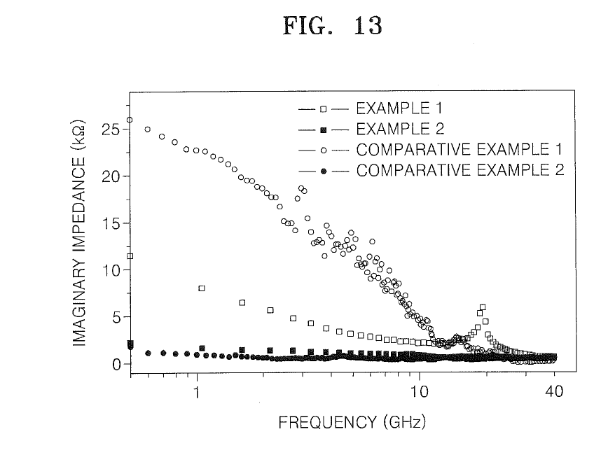

FIG. 12 is a graph illustrating real impedance (kΩ) versus frequency (GHz) of embodiments of graphene obtained according to Examples 1 and 3 and Comparative Examples 1 and 2, and FIG. 13 is a graph illustrating imaginary impedance (kΩ) versus frequency (GHz) of embodiments of graphene obtained according to Examples 1 and 3 and Comparative Examples 1 and 2. As shown in FIGS. 12 and 13, the single-layered graphene obtained using the growth process according to Example 1 has improved characteristics compared to the graphene obtained using the delamination process according to Comparative Example 1. The triple-layered graphene obtained according to Example 3 and Comparative Example 2 had similar characteristics as the single-layered graphene obtained using the growth process according to Example 1.

As described above, according to the one or more of the above embodiments of the invention, the graphene interconnection unit obtained by chemical synthesis is applied to the high frequency circuit, such that conductivity, electron mobility, productivity and reproducibility are substantially improved. In addition, the graphene interconnection unit may be efficiently used in the high frequency circuit due to low electron scattering and efficient positioning.

It should be understood that the embodiments described herein should be considered in a descriptive sense only and not for purposes of limitation. Descriptions of features or aspects within each embodiment should typically be considered as available for other similar features or aspects in other embodiments.

What is claimed is:

1. A high frequency circuit comprising:
a first electronic device;
a second electronic device; and
a graphene interconnection unit comprising graphene and which connects the first and second electronic devices,
wherein an interlayer distance of the graphene is greater than or equal to about 0.34 nanometer.

2. The high frequency circuit of claim 1, wherein the graphene has 2 to 300 layers.

3. The high frequency circuit of claim 1, wherein the first electronic device sends an electrical signal to the second electronic device via the graphene interconnection unit in a high frequency field.

4. The high frequency circuit of claim 1, wherein the graphene is obtained using a growth process.

5. The high frequency circuit of claim 1, wherein the graphene has a randomly stacked structure.

6. The high frequency circuit of claim 1, wherein the first electronic device sends an electrical signal via the graphene interconnection unit at a frequency greater than or equal to about 0.8 gigahertz.

7. The high frequency circuit of claim 1, wherein the first electronic device sends an electrical signal via the graphene interconnection unit at a frequency in a range of about 2 gigahertz to about 300 terahertz.

8. The high frequency circuit of claim 1, wherein each of the first and second electronic devices comprises a transistor.

9. The high frequency circuit of claim 1, wherein the graphene of the graphene interconnection unit comprises a plurality of units, which are aligned substantially parallel to each other.

10. The high frequency circuit of claim 1, wherein the graphene interconnection unit conveys a current at a frequency in a range of about 1 megahertz to about 800 megahertz.

11. The high frequency circuit of claim 1, wherein the graphene interconnection unit conveys a current at a frequency in a range of about 2 gigahertz to about 300 gigahertz.

12. The high frequency circuit of claim 1, wherein the high frequency circuit is a radio frequency circuit which operates at a high frequency greater than or equal to about 0.8 gigahertz.

13. The high frequency circuit of claim 1, wherein a width of the graphene is in range of about 0.001 micrometer to about 1 millimeter.

14. The high frequency circuit of claim 1, wherein a length of the graphene is in range of about 0.001 micrometer to about 100 micrometers.

15. A method of operating a high frequency circuit, the method comprising:
applying a power voltage to the high frequency circuit comprising a graphene interconnection unit; and
conveying a current via the graphene interconnection unit in a high frequency field,
wherein an interlayer distance of graphene of the graphene interconnection unit is greater than or equal to about 0.34 nanometer.

16. A graphene interconnection unit comprising:
graphene having at least two layers,
wherein an interlayer distance of the graphene is greater than or equal to about 0.34 nanometer.
